(19) United States
(12) Patent Application Publication
(10) Pub. No.: US 2023/0207410 A1
(43) Pub. Date: Jun. 29, 2023

(54) LOW STRESS LASER MODIFIED MOLD CAP PACKAGE

(71) Applicant: TEXAS INSTRUMENTS INCORPORATED, Dallas, TX (US)

(72) Inventor: Steven Alfred Kummerl, Carrollton, TX (US)

(21) Appl. No.: 17/562,666

(22) Filed: Dec. 27, 2021

(51) Int. Cl. H01L 23/31; H01L 23/00; H01L 21/56

(52) U.S. Cl. CPC H01L 23/31; H01L 24/06; H01L 21/565

(57) ABSTRACT

An electronic device includes a semiconductor die, a bond wire coupled to a side of the semiconductor die, and a package structure that encloses the semiconductor die and the bond wire. The package structure has a package side with a recess that extends inward from the package side toward the side of the semiconductor die. The recess has a bottom that is spaced apart from the side of the semiconductor die, and the bottom is spaced apart from the bond wire.

### BACKGROUND

Precision electronic devices can be affected by packaging stress causing performance loss. Organic packaging materials having a coefficient of thermal expansion (CTE) different than the silicon material can cause bending stresses in addition to point load stresses. Bending force can shift the circuit performance and cause performance loss in precision circuitry. Adding lower modulus re-passivation layers such as polyimide to the top of the die can reduce the point stresses developed by filler particles in the molded package but overall bending stresses still develop. The use of ceramic materials can help overcome the CTE differences with organic packaging materials, but this adds to device cost and manufacturing complexity. Cavity packages incorporating a lid can reduce stress effects on circuit performance due to the lack of mold compound in direct contact with the silicon and adding silicon spacers within the wire bond periphery also helps but these approaches are also costly, and the bottom die still has regions beyond the spacer that are less stiff and susceptible to bending.

### SUMMARY

In one aspect, an electronic device includes a semiconductor die, a bond wire coupled to a side of the semiconductor die, and a package structure that encloses the semiconductor die and the bond wire. The package structure has a package side with a recess that extends inward from the package side toward the side of the semiconductor die. The recess has a bottom that is spaced apart from the side of the semiconductor die, and the bottom is spaced apart from the bond wire.

In another aspect, a method of packaging a semiconductor die includes performing a molding process that forms a package structure to enclose a semiconductor die and a bond wire and ablating a portion of the package structure to form a recess that extends inward from a package side toward a side of the semiconductor die, the recess having a bottom that is spaced apart from the side of the semiconductor die and from the bond wire.

In a further aspect, a method of fabricating an electronic device includes attaching a semiconductor die to a supporting structure, coupling a bond wire to a side of the semiconductor die, performing a molding process that forms a package structure to enclose the semiconductor die and the bond wire, and ablating a portion of the package structure to form a recess that extends inward from a package side toward the side of the semiconductor die, the recess having a bottom that is spaced apart from the side of the semiconductor die and from the bond wire.

### BRIEF DESCRIPTION OF THE DRAWINGS

FIG. 1 is a top perspective view of a packaged electronic device having recesses formed by laser ablation into a top side of a package structure above stress sensitive of a semiconductor die to mitigate package stress and enhance circuit performance.

FIG. 1A is a partial sectional side elevation view of the electronic device taken along line 1A-1A of FIG. 1.

FIG. 1B is a partial sectional side elevation view of the electronic device taken along line 1B-1B of FIG. 1.

FIG. 2 is a flow diagram of a method of fabricating an electronic device with an included method of packaging a semiconductor die.

FIGS. 3-9 are partial sectional side elevation views of the electronic device of FIG. 1 undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating.

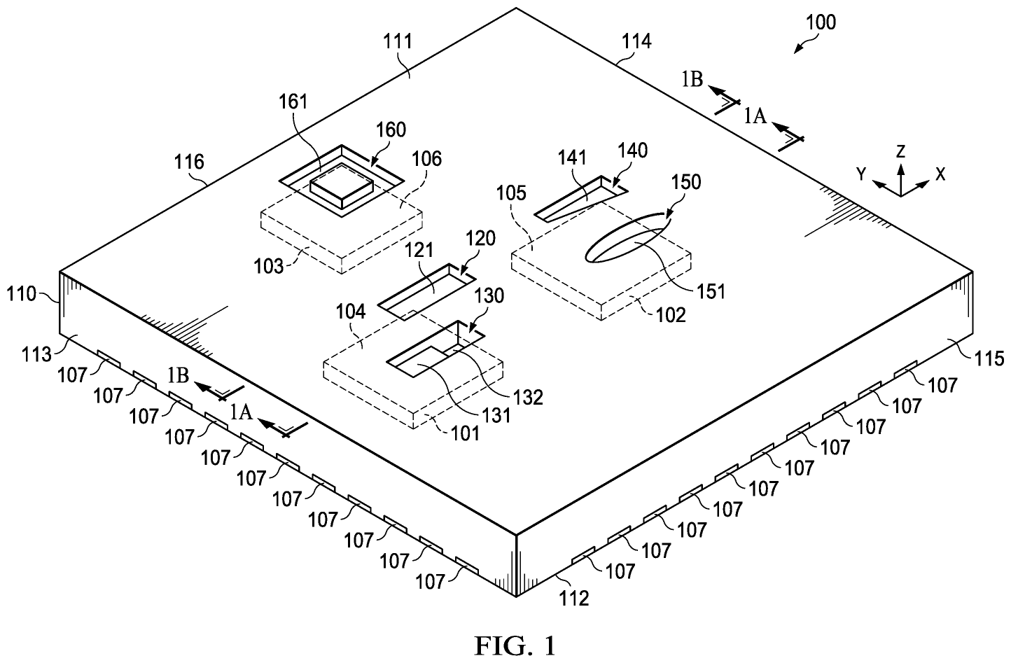

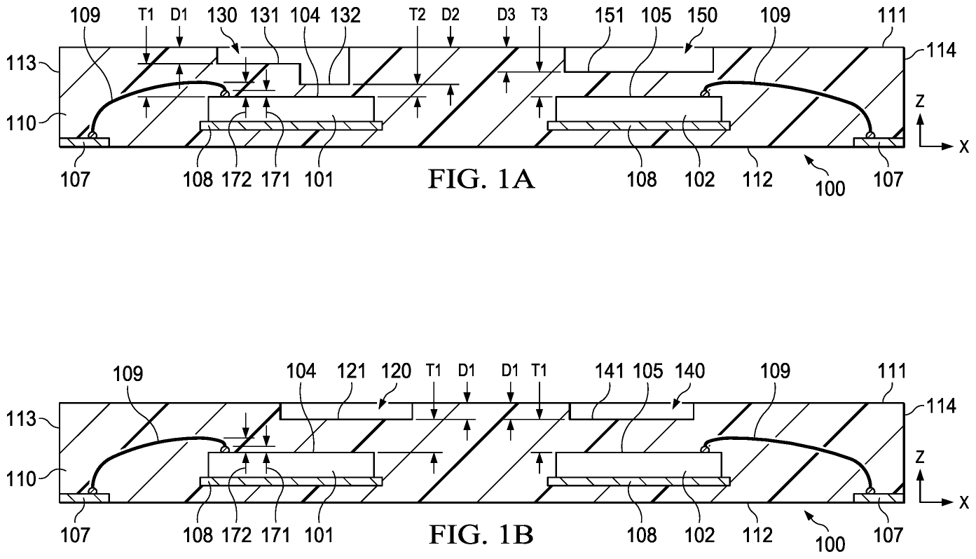

Referring initially to FIGS. 1-1B, FIG. 1 shows a packaged electronic device 100, FIG. lA shows a sectional side view of the electronic device 100 taken along line lA-lA of FIG. 1, and FIG. 1B shows a sectional side elevation view of the electronic device 100 taken along line 1B-1B of FIG. 1. The electronic device 100 includes three semiconductor dies 101, 102, and 103. In other examples, a single semiconductor die is included, or a different number of dies can be included. The first semiconductor die 101 has a first or top side 104. The second semiconductor die 102 has a top side 105, and the third semiconductor die 103 as a top side 106. The sides 104, 105, and 106 of the respective semiconductor dies 101, 102, and 103 can include one or more passivation materials or layers (not shown), as well as conductive features (e.g., copper or aluminum bond pads, not shown) to allow electrical connection to internal circuitry or components of the respective semiconductor dies 101-103. In one example, the passivation layers or materials (e.g., polyamide, not shown) have openings for the conductive bond pads, and may extend overactive circuit portions of the respective semiconductor dies.

The electronic device 100 in this example has a quad flat no lead (QFN) package structure with conductive leads 107 (e.g., terminals) disposed along four sides of the device 100. As shown in FIGS. 1A and 1B, the electronic device 100 further includes die attach pads or other support structures 108 configured to provide mechanical support for the semiconductor dies 101-103. The electronic device also includes conductive bond wires 109 coupled to the sides 104, 105, 106 of the respective semiconductor dies 101-103, for example, to provide electrical coupling between conductive bond pads of the dies 101-103 and/or between conductive bond pads and respective ones of the leads 107.

The electronic device 100 also includes package structure 110 that is or includes molding compound, such as plastic or other molded material. In one example, the material of the package structure 110 includes filler particles, such as rounded silica particles (e.g., silicon dioxide). The package structure 110 is formed in an injection molding process and encloses all or portions of the semiconductor dies 101, 102, 103 and the bond wire 109. As best shown in FIG. 1, the example package structure 110 has a generally rectangular shape with substantially planar first and second (e.g., top and bottom) sides 111 and 112, as well as lateral sides 113 and 114, a front side 115 and a back side 116 in the orientation shown in the figures. The top side 111 of the package structure 110 in the illustrated orientation extends in a plane of orthogonal first and second directions X and Y, respectively. The top sides 104-106 of the respective semiconductor dies 101-103 in this example also extend in X-Y planes of the first and second directions, and the sides 104-106 may, but need not, be coplanar with one another. The sides 113-116 extend along third direction Z between the top and bottom sides 111 and 112 of the package structure 110, where the third side Z is orthogonal to the first and second directions X and Y. Other package forms, shapes, and types can be used in other examples (not shown).

The package structure 110 includes five recesses that extend inward from the top package side 111 downward along the third direction Z. In other examples, a single recess is provided. In further examples, any integer number of two or more recesses can be used. In one implementation, the recesses are created through laser ablation after molding of the starting package structure 110, and the recesses include sidewalls that are generally vertical along the third direction Z, although not a requirement of all possible implementations and other ablation techniques can be used that may, but need not, provide strictly planar vertically oriented sidewalls. The recesses extend at least partially over (e.g., above) the top side 104-106 of at least one of the semiconductor dies 101-103.

The illustrated example includes a first recess 120 having a bottom 121. In the illustrated example, the bottom 121 of the first recess 120 is generally planar in a plane of the first and second directions X and Y. In other examples, non-planar recess bottoms can be used, as well as planar recess bottoms that are not parallel to the X-Y plane of the top package side 111. As best shown in FIG. 1B, the bottom 121 of the first recess 120 is spaced apart from the top side 104 of the first semiconductor die 101 along the third direction Z, and the space between the recess bottom 121 and the top side 104 of the first semiconductor die 101 is filled with the molding compound material of the package structure 110. As shown in FIG. 1B, moreover, the first recess 120 is spaced apart from, and extends above a portion of the first semiconductor die 101, and the first recess 120 extends laterally outward along the first direction X beyond the lateral side of the first semiconductor die 101.

As shown in FIGS. 1 and 1A, the example package structure 110 also includes a second recess 130 that extends inward from the package side 111 downward along the third direction Z. The second recess 130 is a multilevel recess that includes a first portion with a first bottom 131, as well as a second portion having a second bottom 132. The respective first and second bottoms 131 and 132 in this example are generally planar and lie in respective planes of the first and second directions X and Y, although not a requirement of all possible implementations. As shown in FIG. 1A, the first and second bottoms 131 and 132 are spaced apart from the top side 104 of the first semiconductor die 101, and the second portion of the second recess 130 is deeper than the first portion. In addition, the first and second bottoms 131 and 132 are spaced apart from the bond wires 109 of the electronic device 100, for example, such that the bond wires 109 are completely enclosed by the package structure 110.

The second recess 130 in one example has a first depth D1 from the package side 111 to the bottom 131 of the first portion of 50 μm or more. In addition, the second recess 130 has a second depth D2 from the top package side 111 to the second bottom 132 of 50 μm or more, where the second depth D2 is greater than the first depth D1. The package structure 110 has a first spacing thickness T1 between the bottom 131 of first portion and the top side 104 of the first semiconductor die 104 of 25 um or more. In addition, the package structure 110 in this example has a second spacing thickness T2 between the second bottom 132 of the second portion and the top side 104 of the first semiconductor die 104 of 25 um or more. The spacing thickness is T1 and T2 and other thicknesses of the package structure 110 can be tailored for a given design and are generally maintained at a minimum value (e.g., 25 μm or more) to facilitate fluidic flow of melted molding material during fabrication in an injection molding operation to facilitate complete filling, as well as to provide a minimum package material thickness for electrical isolation with respect to circuitry or terminals of the semiconductor dies 101-103. In the illustrated example, the first and second portions of the second recess 130 both extend above, and are spaced apart from, the top side 104 of the first semiconductor die 101 along the third direction Z, although not a requirement of all possible implementations. In other examples, moreover, a recess can include more than two portions at more than two different levels (e.g., different depths beneath the top package side 111).

A third recess 140 is illustrated in FIGS. 1 and 1B, which includes a generally planar third bottom 141 extending in an X-Y plane that is generally parallel to the plane of the top package side 111. As shown in FIG. 1B, the third recess 140 has the depth D1 along the third direction Z from the package side 111 to the third bottom 141 of 50 μm or more, and the package structure 110 has the spacing thickness T1 between the third bottom 141 and the top side 105 of the second semiconductor die 102. As shown in FIG. 1, the third recess 140 has a tapered profile extending generally along the first direction X. In other examples, one or more recesses can be formed of any profile, shape, etc.

FIGS. 1 and 1A illustrate an example fourth recess 150 that extends inward from the package side 111 downward along the third direction Z. The fourth recess 150 has a fourth bottom 151 that is generally planar in a plane of the first and second directions X and Y. The fourth recess 150 has a third depth D3 that is greater than the first depth D1 and less than the second depth D2. In one implementation, the recess depths (e.g., D1-D3) are provided by control of an ablation process, such as laser ablation during fabrication, and the recess depths are 50 μm or more, for example, in order to facilitate mechanical stress mitigation in select portions or regions of the electronic device 100, such as above select areas of the top sides of a proximate semiconductor die.

The package structure 110 has a third spacing thickness T3 between the fourth bottom 151 of fourth recess 150 and the top side 105 of the second semiconductor die 102 of 25 um or more. As shown in FIG. 1, moreover, the fourth recess 150 has a curvilinear (e.g., oval) profile with a longer dimension extending generally along the first direction X. The package structure 110 in this example also includes a fifth recess 160 that extends inward from the package side 111 downward along the third direction Z. The fifth recess 160 includes a fifth bottom 161 and extends in a generally rectangular circuitous moat-shaped profile above the top side 106 of the third semiconductor die 103.

The bottoms of the example recesses 120, 130, 140, 150, and 160 provide selectively thinned package structure material above select portions of the respective semiconductor dies 101-103. In one implementation, the select portion or portions of the semiconductor dies 101-103 above which a recess is formed, and the associated depth and package structure spacing thickness are tailored for a given semiconductor die to preferentially provide thinner package structure material above certain active circuitry of the associated semiconductor die, for example, circuits whose performance in operation are sensitive to mechanical stress. In this regard, the thinned portions of the package structure material beneath and around the recesses 120, 130, 140, 150, and 150 mitigate or reduce mechanical stress applied to the proximate portions of top sides of the respective semiconductor dies, and the ablation techniques described below can be tailored to fabricate recesses of any desired shape and location for selective control of stress to enhance electrical circuit performance of the electronic device 100.

In addition, as shown in FIGS. lA and 1B, the location in the capital X and Y directions, as well as the shape and depth of one or more of the recesses can be tailored in order to maintain a desired minimum package material spacing thickness around, above and/or alongside the bond wires 109 (e.g., 25 μm or more). As shown in FIGS. 1A and 1B, advanced low profile wire bonding can be used to form the bond wires 109, for example, to maintain or control a first distance 171 between the top side 104 of the first semiconductor die 101 (e.g., 20 μm or more) along the third direction Z, as well as to control a second distance 172 along the third direction Z between the top side 104 of the first semiconductor die 101 and the top of the bond wire 109. The location and depth of the recess or recesses can be controlled in view of the wire bond extents and positions (e.g., to maintain a minimum package material spacing thickness between the bond wires 109 and a proximate recess bottom or sidewall) for a given wire bonding process technology. In this regard, the recess or recesses in a given electronic device design can be tailored to selectively facilitate mechanical stress reduction with respect to bond wires 109 and/or connections thereof to bond pads of semiconductor dies and/or connection to the leads 107.

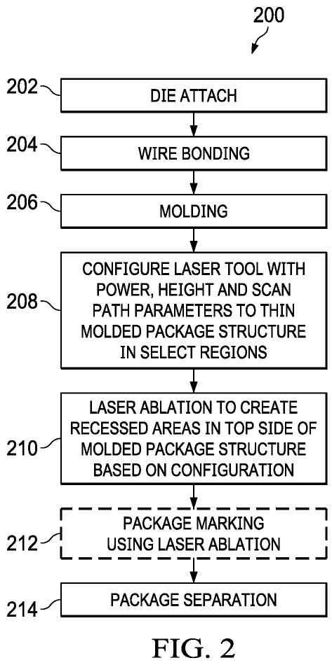

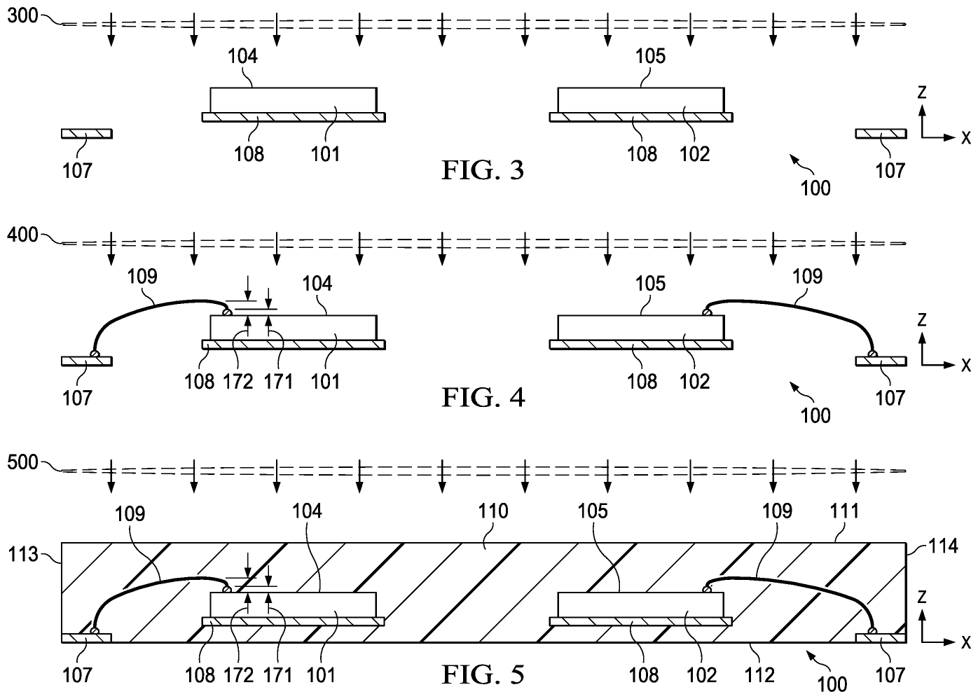

Referring also to FIGS. 2-9, FIG. 2 shows a method 200 of fabricating an electronic device with an included method of packaging a semiconductor die, and FIGS. 3-9 show the electronic device 100 of FIG. 1 undergoing fabrication processing according to the method 200. FIGS. 3-9 illustrate section views of a portion of the example electronic device 100, for example, along line 1A-1A of FIG. 1. Following wafer processing (not shown), the method 200 includes die attach processing at 202. FIG. 3 shows one example, in which a die attach process 300 is performed that attaches the semiconductor dies (dies 101 and 102 illustrated in the section view of FIG. 3) to the respective die attach pads 108. In the illustrated implementation, the semiconductor dies are attached to the associated die attach pads of a starting lead frame, for example, in an array or panel structure with rows and columns of prospective electronic device areas, only one of which is shown in FIGS. 3-9. In another implementation, the semiconductor die, or dies are attached at 102 to a different form of supporting structure, for example, flip-chip die attach and reflow soldering to a package substrate (not shown).

The method 200 in FIG. 2 wire bonding at 204. FIG. 4 shows one example, in which a wire bonding process 400 is performed that electrically couples bond wires 109 to the top sides of one or more of the semiconductor dies 101-103, for example, to conductive bond pads on the top sides 104 and 105 of the illustrated first and second semiconductor dies 101 and 102, respectively. In the illustrated example, the bond wires 109 are coupled between the respective semiconductor dies 101 and 102 and a respective one of the conductive leads 107 of a starting lead frame structure. In one implementation, the wire bonding at 204 also includes forming one or more bond wire connections between two of the semiconductor dies 101-103 (not shown in the illustrated section view of FIG. 4).

At 206 in FIG. 2, the method 200 also includes molding at 206. FIG. 5 shows one example, in which a molding process 500 is performed that forms the starting package structure 110 to enclose the semiconductor dies 101-103 and the bond wires 109. In this example, the associated mold (e.g., mold chase, not shown) includes a generally planar bottom side that faces, and is spaced apart from, the top sides 104-106 of the respective semiconductor dies 101-103, and the associated mold has no mold features associated with the subsequently formed recess as discussed above. In this regard, the package side 111 shown in FIG. 5 has a generally planar surface with no recesses immediately following the molding process 500 of FIG. 5. This advantageously allows the use of a single mold for a given package form and type (e.g., a QFN mold), while the geometry, shapes, depths, and locations of the subsequently formed recesses (e.g., 120, 130, 140, 150, and 160) can be tailored and modified to accommodate stress reduction in a potentially large number of different product designs having recess features tailored for circuitry of a given semiconductor die design and bond wire locations for a given packaging design. The formation of recesses by ablation, as discussed further below, moreover, facilitates reconfiguration of recesses in the finished device package structure 110, for example, when a new semiconductor die design is introduced, or a die is redesigned, and/or when a bond wire arrangement is changed. The described method 200, and the included ablation-based recess formation method discussed below, allow dynamic manufacturing modifications such as these without the time and expense of redesigning and producing new molds.

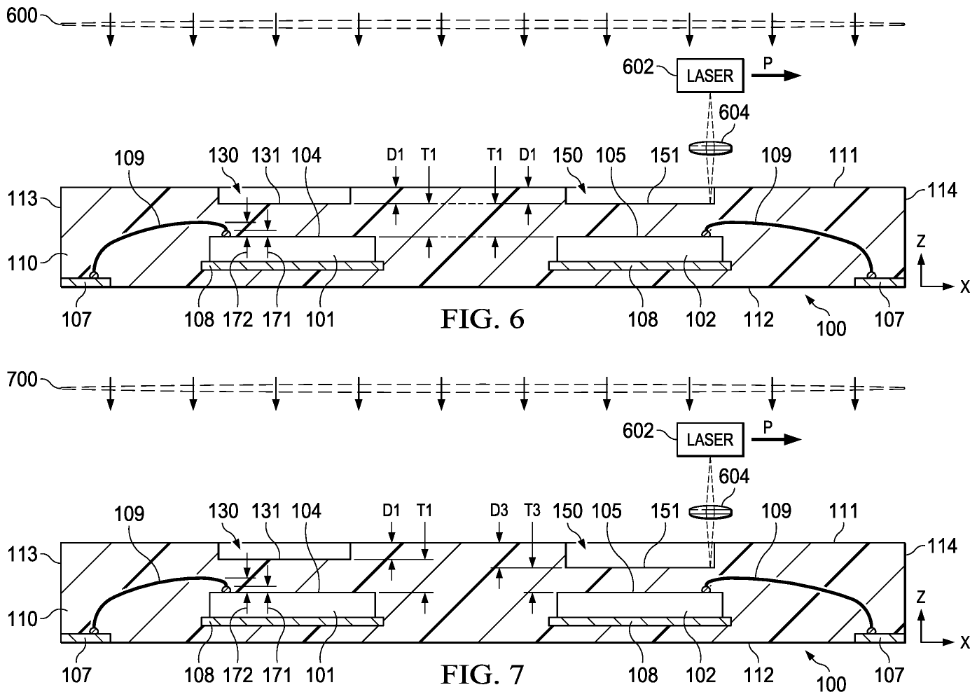

The method 200 also includes ablation processing at 208-212. Any suitable ablation process can be used, such as laser ablation, evaporation, or other technique by which select portions of the package side 111 are removed to form the recesses for controlling mechanical stress in the finished electronic device 100. In the illustrated example, a laser tool is configured at 208 with power, height, and scan path parameters to selectively thin the molded package structure in one or more select regions. At 210, the method 200 continues with ablating one or more portions of the package structure 110 to form associated recesses (e.g., 120, 130, 140, 150, 160 above) that extend inward from the package side 111 toward the sides 104-106 of the associated semiconductor dies 101-103. FIGS. 6-9 illustrate one example implementation, in which a laser 602 is operated at a configured power setting and focal distance set by a focusing lens 604 in multiple passes, with a position control apparatus (not shown) translating the laser 602 along a raster scan path P to form the example recesses. In one implementation, the laser 602 is raster scan and for individual recesses with a generally constant control power, and the raster scanning speed is controlled to achieve a desired depth. In this or another implementation, multiple passes can be used to form associated portions of a multi-level recess (e.g., the first recess 120 with first and second portions). In another implementation, the raster scanning speed can be higher for thinner portions, and the laser translation along the raster scan path P is slowed down for deeper portions of a given recess, or raster scanning speed can be adjusted for different speeds to achieve different depths of different desired recesses in a single raster scan operation.

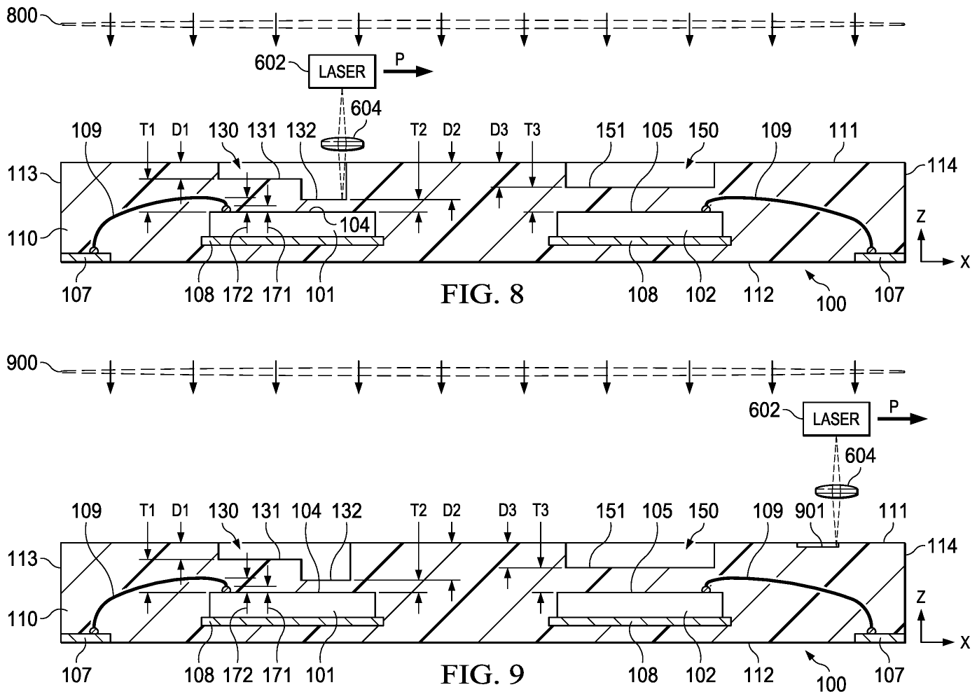

FIG. 6 shows a first laser ablation process pass 600, in which the laser 602 generates and directs a laser beam downward along the third direction Z toward the top package side 111 to create recessed areas to the first depth D1, including the first portion of the second recess 130 and an initial portion of the fourth recess 150. FIG. 7 shows a second laser ablation process pass 700, in which the laser 602 generates and directs the laser beam downward along the third direction Z to increase the depth D3 of the fourth recess 150 and reduce the spacing thickness T3 to the desired values for a given design. FIG. 8 shows an example third laser ablation process pass 800, in which the laser 602 directs the laser beam downward to further increase the depth D2 and reduce the thickness T to associated with the second portion of the second recess 130. The ablation processing at 210 continues until all the desired recesses have been formed in the top package side 111 of the package structure 110. In one implementation, the ablation processing at 210 is performed across a panel or array with multiple rows and columns of prospective electronic device areas, and the ablation tool configuration at 208 provides the necessary programming and configuration of the ablation tool power, height, speed, and scan path parameters to accommodate the panel-level processing of multiple electronic device areas in a single process.

In one example, the method 200 of FIG. 2 further includes package marketing at 212 by ablation. In one example, the ablation tool (e.g., laser tool) employed for the recess creation at 210 is also used for package marketing at 212, although separate ablation tools can be used in another implementation. The package marketing at 212 in one example creates very shallow indentations relative to the depths D1-D3 of the recesses, where the package marketing indentations have depths that are typically 30 μm or less, whereas the example recesses have depths of 50 μm or more. Moreover, the selective location, depths, etc. of the recesses 120, 130, 140, 150, and 160 are strategically selected to mitigate package stress with respect to a given device and semiconductor design and/or bond wire configuration, the package marketing indentations are generally in a fixed position, such as in an upper corner of the finished package structure 110 respective of stress impacts, and the shallow package marketing indentations are not intended for package stress modification. FIG. 9 shows one example, in which another ablation process pass 900 is performed that creates shallow indentations through ablation of small portions of the top package side 111 to create a product serial number, batch code, or other information useful to a manufacturing process (e.g., for subsequent use by pick and place machinery in a printed circuit board assembly process, not shown), where the package marketing can be in the form of human readable text or numbers, barcodes, or other patterns or codes (not shown). In another implementation, the package marketing at 212 is omitted.

The method 200 continues at 214 in FIG. 2, with package separation. In one example, laser or saw cutting tools (not shown) are operated at 214 in order to selectively cut between adjacent die areas of the processed panel structure along boundaries of rows and columns, in order to separate individual finished packaged electronic devices (e.g., device 100 in FIG. 1) from one another. The package separation processing at 214 can include lead trimming and forming operations, for example, to create gullwing or J-type leads, final device testing (not shown) as well as other useful or optional finishing steps (not shown) in order to produce a finished packaged electronic device.

Described examples selectively create a thin mold cap package with single or multi-pass laser ablation to further thin the mold cap over selective stress sensitive regions of the package to mitigate stress and facilitate enhanced performance, for example, in high precision devices. In practice, existing laser ablation tooling can be used without adding significant process cost or complexity, for example, using high thru-put laser symbolization equipment capable of highly controlled mold compound removal for package marketing, with additional configuration (e.g., at 208 in FIG. 2 above) to implement rasterized scanning across an area multiple times to create any desired recesses in the package structure 110. The provision of the recesses 120, 130, 140, 150, and 160 provides a customized low profile mold cap, in combination a low-profile wire bonded package above the sensitive circuit of interest, and effectively reduces the force exerted by the mold compound to facilitate better overall accuracy and precision. The above-described techniques and packaged electronic devices facilitate electronic device manufacturing with greater flexibility in design, along with programmatic adaptability to design improvements or changes without the expense of new molds or other packaging production tooling. This allows different programs to be created and modified for production of a number of different device and die designs while using a single mold tool for a given package type and size (e.g., low nonrecurring engineering costs).

In addition to manufacturing cost and complexity savings, the described solutions reduce the overall stress and operation of the finished packaged electronic device 100 since the region or regions above and surrounding the sensitive circuitry will be a thin film of mold material. These solutions and approaches also facilitate the ability to reduce the global strain in addition to the point stress effect to help produce a much higher performance device that is less sensitive to stress effects. In addition, the described examples mitigate or avoid dimensional limitations from stacking a spacer or creating a hard tooled open cavity feature.

Modifications are possible in the described examples, and other implementations are possible, within the scope of the claims.

What is claimed is:

1. An electronic device, comprising:
a semiconductor die having a side;
a bond wire coupled to the side of the semiconductor die; and
a package structure that encloses the semiconductor die and the bond wire, the package structure having a package side with a recess that extends inward from the package side toward the side of the semiconductor die, the recess having a bottom that is spaced apart from the side of the semiconductor die, and the bottom is spaced apart from the bond wire.

2. The electronic device of claim 1, wherein the package structure has a spacing thickness between the bottom of the recess and the side of the semiconductor die of 25 um or more.

3. The electronic device of claim 2, wherein the recess has a depth from the package side to the bottom of the recess of 50 μm or more.

4. The electronic device of claim 3, wherein the package structure has a second spacing thickness between the bottom of the recess and the bond wire of 25 um or more.

5. The electronic device of claim 3, wherein the recess extends over a select portion of the semiconductor die.

6. The electronic device of claim 3, comprising a further recess that extends inward from the package side toward the side of the semiconductor die, the further recess having a further bottom that is spaced apart from the side of the semiconductor die, and the further bottom is spaced apart from the bond wire.

7. The electronic device of claim 1, wherein:
the recess includes first and second portions;
the first portion has the bottom;
the recess has a first depth from the package side to the bottom of the first portion of 50 μm or more;
the second portion has a second bottom that is spaced apart from the side of the semiconductor die and spaced apart from the bond wire;
the recess has a second depth from the package side to the second bottom of 50 μm or more, the second depth is greater than the first depth;
the package structure has a first spacing thickness between the bottom of first portion and the side of the semiconductor die of 25 um or more; and
the package structure has a second spacing thickness between the second bottom of the second portion and the side of the semiconductor die of 25 um or more.

8. The electronic device of claim 1, wherein the recess has a depth from the package side to the bottom of the recess of 50 μm or more.

9. The electronic device of claim 1, wherein the package structure has a second spacing thickness between the bottom of the recess and the bond wire of 25 um or more.

10. The electronic device of claim 1, wherein the recess extends over a select portion of the semiconductor die.

11. The electronic device of claim 1, comprising a further recess that extends inward from the package side toward the side of the semiconductor die, the further recess having a further bottom that is spaced apart from the side of the semiconductor die, and the further bottom is spaced apart from the bond wire.

12. A method of packaging a semiconductor die, the method comprising:
performing a molding process that forms a package structure to enclose a semiconductor die and a bond wire, the package structure having a package side; and
ablating a portion of the package structure to form a recess that extends inward from the package side toward a side of the semiconductor die, the recess having a bottom that is spaced apart from the side of the semiconductor die and from the bond wire.

13. The method of claim 12, wherein the package structure has a spacing thickness between the bottom of the recess and the side of the semiconductor die of 25 um or more.

14. The method of claim 12, wherein the recess has a depth from the package side to the bottom of the recess of 50 μm or more.

15. The method of claim 12, wherein the package structure has a second spacing thickness between the bottom of the recess and the bond wire of 25 um or more.

16. The method of claim 12, wherein the recess extends over a select portion of the semiconductor die.

17. A method of fabricating an electronic device, the method comprising:
attaching a semiconductor die to a supporting structure;
coupling a bond wire to a side of the semiconductor die;
performing a molding process that forms a package structure to enclose the semiconductor die and the bond wire, the package structure having a package side; and
ablating a portion of the package structure to form a recess that extends inward from the package side toward the side of the semiconductor die, the recess having a bottom that is spaced apart from the side of the semiconductor die and from the bond wire.

18. The method of claim 17, wherein the package structure has a spacing thickness between the bottom of the recess and the side of the semiconductor die of 25 um or more.

19. The method of claim 17, wherein the recess has a depth from the package side to the bottom of the recess of 50 μm or more.

20. The method of claim 17, wherein the package structure has a second spacing thickness between the bottom of the recess and the bond wire of 25 um or more.
